(19) United States
(12) Patent Application Publication
(10) Pub. No.: US 2016/0351522 A1
(43) Pub. Date: Dec. 1, 2016

(54) PACKAGE-ON-PACKAGE DEVICE AND CAVITY FORMATION BY SOLDER REMOVAL FOR PACKAGE INTERCONNECTION

(71) Applicant: FREESCALE SEMICONDUCTOR, INC., Austin, TX (US)

(72) Inventors: MICHAEL B. VINCENT, Chandler, AZ (US); Zhiwei Gong, Chandler, AZ (US)

(21) Appl. No.: 14/723,007

(22) Filed: May 27, 2015

(51) Int. Cl. H01L 23/00; H01L 21/56; H01L 23/31; H01L 25/10; H01L 25/00

(52) U.S. Cl. CPC H01L 24/14; H01L 25/105; H01L 25/50; H01L 23/3114; H01L 21/565; H01L 24/11; H01L 24/81; H01L 2224/16237; H01L 2224/11436; H01L 2224/1184; H01L 2224/11848; H01L 2224/8112; H01L 2224/81947; H01L 2224/81948; H01L 2225/1058

(57) ABSTRACT

In an electronic package that includes an electronic component, a method of forming one or more cavities in the electronic package includes depositing solder material on at least one terminal of the electronic component, encapsulating the electronic component and the solder material in an encapsulant, exposing a top surface of the solder material from the encapsulant, and removing the solder material such that a cavity remains at a location in the encapsulant where the solder material was removed. The solder material can be removed by a hot air solder removal process to yield one or more cavities having a consistent size and shape. In a package-on-package (PoP) process, solder balls on an active surface of another electronic package are positioned in the one or more cavities in alignment with the terminals, and the solder balls are attached to the terminals via solder reflow to produce a PoP device.

### TECHNICAL FIELD OF THE INVENTION

The present invention relates generally to electronic device packaging. More specifically, the present invention relates to cavity formation by solder removal for package interconnections in package-on-package (PoP) configurations.

### BACKGROUND OF THE INVENTION

High performance, high speed, and small electronic components are increasingly being demanded in the electronics industry. Ball grid array (BGA) type packaging techniques are widely used in order to satisfy these demands. The ball grid array may include solder balls bonded to a bottom surface of a package substrate. The package substrate may be mounted on a printed circuit board (PCB) with the solder ball therebetween. These ball grid array-type package techniques may increase the number and a density of pins of a semiconductor package.

Stacked packaging schemes, such as package-on-package (PoP) packaging, are also becoming increasingly popular to further meet the demands of high performance, high speed, and small form factor electronic components. In general, PoP packaging is an integrated circuit packaging method implemented to vertically combine discrete ball grid array packages. Two or more packages can be installed atop one another, i.e., stacked, with an interface to route signals between them. Solder balls may be used in order to connect an upper semiconductor package to a lower semiconductor package in a PoP device. Thus, PoP packaging techniques can enable higher component density, higher package yields (since only “known good” packages are used in final assembly), enhanced component flexibility, and so forth.

In some techniques, the solder balls can be embedded into the mold compound of fan-out wafer level packages (FO-WLP) and the like to form vertical electrical interconnects to allow stacking of PoP packages. In order to gain access to the embedded solder balls, laser ablation is currently used to form cavities through the mold compound. Laser ablation is performed one solder ball at a time and is therefore a slow and costly process. Additionally, heat from the laser can cause damage to the mold compound, leaving an irregular cavity opening edge. This irregular cavity opening can result in the misalignment of vias and solder joint unreliability.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a simplified cross-sectional side view of a package-on-package (PoP) device in accordance with an embodiment;

FIG. 2 shows a simplified partial cross-sectional side view of a portion of another PoP device in accordance with another embodiment;

FIG. 3 shows a partial perspective view of an electronic package and a corresponding enlarged portion of the electronic package;

FIG. 4 shows a flowchart of a cavity formation process 100 that may be used for package interconnection in PoP device configurations in accordance with another embodiment;

FIG. 5 shows a side sectional view of a structure at an initial stage of processing in accordance with the process of FIG. 4;

FIG. 6 shows a side sectional view of the structure of FIG. 5 at a subsequent stage of processing;

FIG. 7 shows a side sectional view of the structure of FIG. 6 at a subsequent stage of processing;

FIG. 8 shows a side sectional view of the structure of FIG. 7 at a subsequent stage of processing;

FIG. 9 shows a side sectional view of the structure of FIG. 8 at a subsequent stage of processing;

FIG. 10 shows a side sectional view of the structure of FIG. 9 at a subsequent stage of processing;

FIG. 11 shows a side sectional view of a structure at an initial stage of processing in accordance with another embodiment of the process of FIG. 4;

FIG. 12 shows a side sectional view of the structure of FIG. 11 at a subsequent stage of processing;

FIG. 13 shows a side sectional view of the structure of FIG. 12 at a subsequent stage of processing;

FIG. 14 shows a side sectional view of the structure of FIG. 13 at a subsequent stage of processing;

FIG. 15 shows a side sectional view of the structure of FIG. 14 at a subsequent stage of processing;

FIG. 16 shows a side sectional view of the structure of FIG. 15 at a subsequent stage of processing; and

FIG. 17 shows a flowchart of a package-on-package fabrication process that incorporates the cavity formation process of FIG. 4.

### DETAILED DESCRIPTION

In overview, embodiments of the present invention entail a package-on-package (PoP) device, a method of cavity formation by solder removal for package interconnections, and a method for fabricating the PoP device that incorporates the cavity formation methodology. The cavity formation methodology provides high throughput and damage free formation of mold cavities by the use of hot air/vacuum removal of solder material embedded in a mold compound. The mold cavities may be used for the purpose of package to package interconnection, such as in a PoP configuration. Additionally or alternatively, the cavity formation methodology may be used to form package interconnections on top of an electronic package for interconnection with other components such as surface mount devices. Additionally, the cavity formation methodology may be used to form electrically conductive pads for probing the top side of an electronic package during testing of the package individually or after it has been assembled to a printed circuit board (PCB).

The instant disclosure is provided to further explain in an enabling fashion the best modes, at the time of the application, of making and using various embodiments in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued. It should be further understood that the use of relational terms, if any, such as first and second, top and bottom, and the like are used solely to distinguish one from another entity or action without necessarily requiring or implying any actual such relationship or order between such entities or actions.

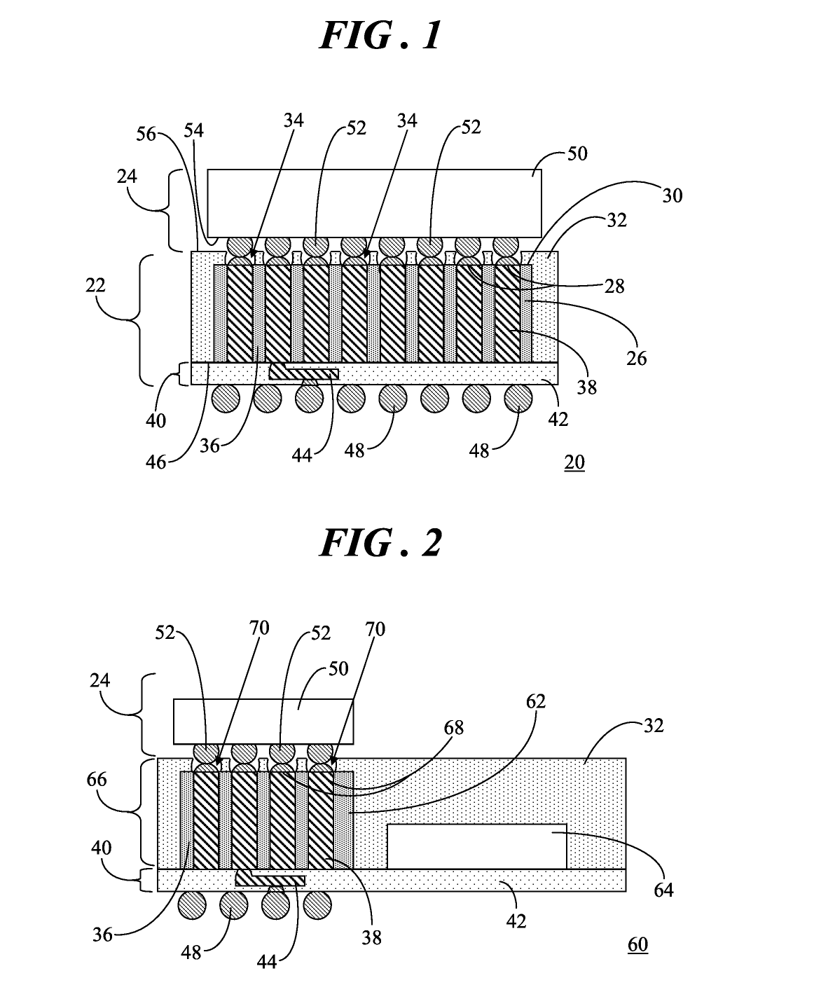

Referring to FIG. 1, FIG. 1 shows a simplified cross-sectional side view of a package-on-package (PoP) device 20 in accordance with an embodiment. PoP device 20 includes a first electronic package 22 and a second electronic package 24 attached to first electronic package 22. Second electronic package 24 is illustrated in FIG. 1 as being on top of first electronic package 22. Accordingly, first electronic package 22 is referred to hereinafter as bottom electronic package 22, and second electronic package 24 is referred to hereinafter as top electronic package 24. FIG. 1 and subsequent FIGS. 2, 3, and 5-16 are illustrated using various shading and/or hatching to distinguish the various elements from one another for clarity of illustration. These different elements within the structural layers may be produced utilizing a wide variety of current and upcoming manufacturing techniques.

Bottom electronic package 22 includes at least one electronic component 26 having a plurality of terminals 28 exposed from or otherwise formed at a top surface 30 of electronic component 26. An encapsulant 32, also commonly referred to as a mold compound or a casting compound, generally encapsulates electronic component 26 and terminals 28. However, multiple cavities 34 extend through encapsulant 32 to at least partially enable the interconnection of terminals 28 with top electronic package 24. In the illustrated configuration, electronic component 26 may include a dielectric substrate material 36 having electrically conductive through-vias 38 extending through substrate material 36, with a top surface of each of electrically conductive through-vias 38 being one of terminals 28. In alternative embodiments, one or more vias 38 may be electrically coupled to a corresponding one or more electrically conductive elongated features or traces (sometimes referred to as a dog-bone) formed on top surface 30 of electronic component 26. A distal end of this conductive feature may thus be one of terminals 28 of electronic component 26. Electronic component 26 may additionally include circuit elements not shown herein for simplicity of illustration.

A redistribution structure 40 that includes one or more layers of dielectric material 42 suitably separating one or more layers of electrically conductive redistribution traces 44 (one shown) may be formed on a bottom surface 46 of electronic component 26. Solder balls 48, interconnected with redistribution traces 44, can thereafter be formed on redistribution layer 40. In an end use application, solder balls 48 may be used to interconnect first electronic package 22 to a printed circuit board (not shown), to another electronic package (not shown), and the like. Although solder balls 48 are shown herein, alternative embodiments may implement contacts in a land grid array packaging configuration or any other suitable contact configuration.

Top electronic package 24 includes a second electronic component 50 and solder balls 52 extending from an active surface 54 of second electronic component 52. Solder balls 52 are positioned in cavities 34 extending through encapsulant 32 of bottom electronic package 22 with one each of solder balls 52 being in alignment with one each of terminals 28. Solder balls 52 are attached to their associated terminals 28 using, for example, a solder reflow process in order to couple top electronic package 24 with bottom electronic package 22.

In FIG. 1, top electronic package 24 is shown slightly spaced apart from a top surface 56 of bottom electronic package 22, and empty space is shown within cavities 34 of bottom electronic package 22, in order to distinguish top electronic package 24 from bottom electronic package 22. Additionally, a gap is shown between electronic packages 22 and 24. This gap may be desired when, for example, top electronic package 24 is underfill encapsulated. In other embodiments, however, following the reflow soldering process, the solder material of solder balls 52 generally fills each of cavities 34. Additionally, active surface 54 of top electronic package 24 may be in direct contact with top surface 56 of bottom electronic package 22. Accordingly, solder balls 52 and cavities 34 are suitably formed so that the material volume of solder used to form each solder ball 52 is approximately equivalent to the cavity volume of its corresponding cavity 34. It should be observed that encapsulant 32 is retained between adjacent cavities 34. Thus, following attachment of top electronic package 24 to bottom electronic package 22, each of the solder connections formed between solder balls 52 and terminals 28 is electrically isolated from its neighboring solder connections.

Referring to FIG. 2, FIG. 2 shows a simplified partial cross-sectional side view of a portion of another PoP device 60. In this example, PoP device 60 includes multiple electronic components 62, 64 (two shown) encapsulated within encapsulant 32 to form a bottom, i.e., first, electronic package 66. Like electronic component 26, electronic component 62 also includes dielectric substrate material 36 having electrically conductive through-vias 38 extending through substrate material 36. Bottom electronic package 66 may include additional electronic components that are not shown for simplicity. In this illustrated configuration, solder balls 52 of top electronic package 24 are attached to terminals 68 of electronic component 62 within cavities 70 formed in encapsulant 32.

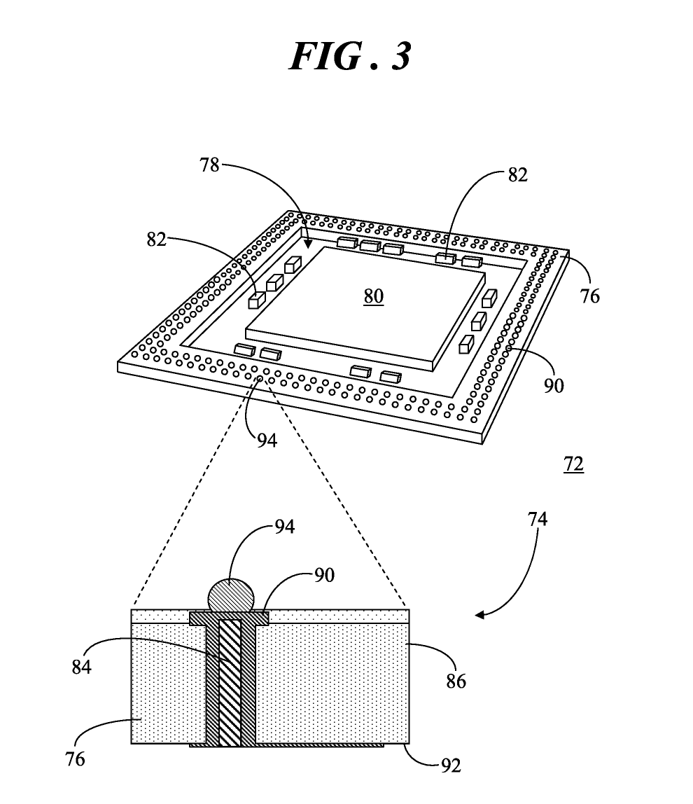

FIG. 3 shows a partial perspective view of yet another electronic package 72 and a corresponding enlarged portion 74 of electronic package 72. In this illustration, electronic package 72 is not embedded in encapsulant 32 (FIG. 1) so that the multiple electronic components that make up electronic package 72 may be visualized. However, it should be understood that electronic package 72 including its multiple electronic components can eventually be embedded in encapsulant 32 to form a system-in-package device. The electronic components may include a frame structure 76 having a central opening 78 (e.g., window), a logic element 80 and multiple discrete components 82 (e.g., surface mount resistors, capacitors, and the like). Logic element 80 and discrete components 82 may be positioned within central opening 78.

Of particular interest in FIG. 3 is the presence of a plurality of electrically conductive through-vias 84 formed in and extending through a substrate 86 of frame structure 76. A side view of one of through-vias 84 is shown in enlarged portion 74 to better visualize its structure. A top surface of through-via 84 is an electrically conductive terminal 90 or is otherwise interconnected with conductive terminal 90. A bottom surface 92 of frame structure 76 may include a redistribution layer (not shown) or any other structural features capable of carrying electrically conductive traces, bond pads, and the like in order to interconnect the various components (e.g. conductive through-vias 84 of frame structure 76, logic element 80, and discrete components 82) with one another in accordance with a particular design configuration. Alternatively, in an end use application, electronic package 72 may be attached to a printed circuit board that carries the electrically conductive traces, bond pads, and the like to interconnect the various components of electronic package.

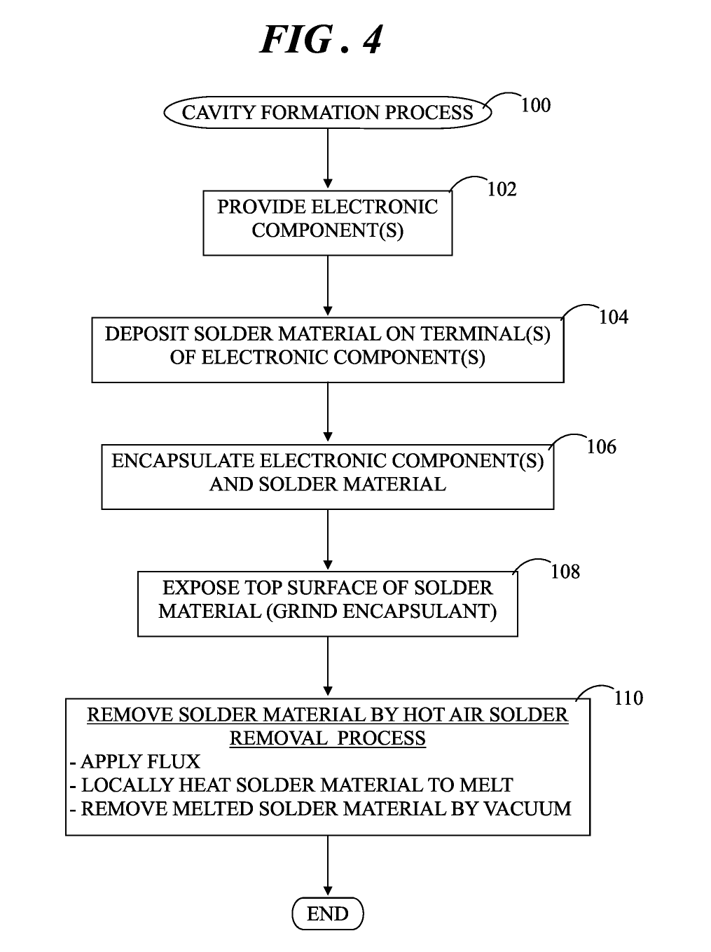

In accordance with particular methodology discussed in connection with FIG. 4, solder material 94 is deposited or otherwise formed on one or more terminals 90 of frame structure 76. Solder material 94 is deposited at the locations at which cavities (e.g., cavities 34 of FIG. 1 or cavities 70 of FIG. 2) are to be formed in the encapsulant in which frame structure 76, logic element 80, and discrete components 82 will be embedded. Like frame structure 76, logic element 80, and discrete components 82, solder material 94 will be embedded in the encapsulant. Methodology described in connection with FIG. 4 entails a method of cavity formation by removing the solder material (e.g., solder material 94) in order to provide package interconnections between a bottom electronic package (e.g., bottom electronic package 22 of FIG. 1, bottom electronic package 66 of FIG. 2, or electronic package 72 of FIG. 3) and a top electronic package (e.g., top electronic package 24 shown in FIGS. 1 and 2) to produce a package-on-package device.

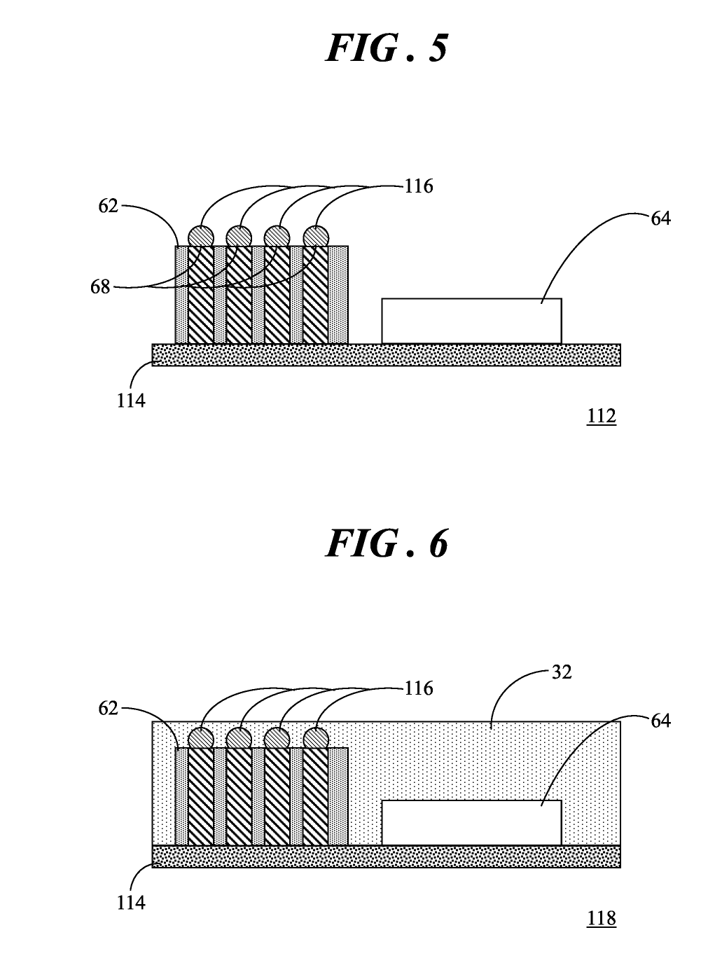

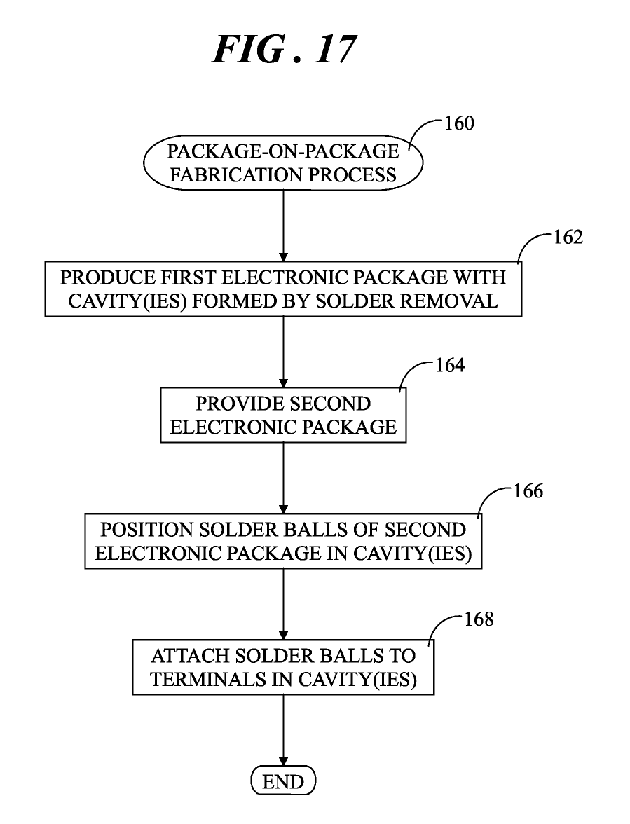

FIG. 4 shows a flowchart of a cavity formation process 100 in accordance with another embodiment. In general, cavity formation process 100 provides methodology for forming cavities in a mold compound by solder removal. The cavity formation methodology of process 100 enables high throughput and damage free formation of mold cavities by the use of hot air/vacuum removal of solder material embedded in a mold compound. The mold cavities may be used for the purpose of package to package interconnection, such as in a PoP configuration, as will be discussed in connection with FIG. 17. Additionally or alternatively, cavity formation process 100 may be used to form package interconnections on top of an electronic package for interconnection with other components such as surface mount devices. And still further, cavity formation process 100 may be used to form electrically conductive pads for probing the top side of an electronic package during testing of the package individually or after it has been assembled to a PCB. FIG. 4 provides a generalized description of the operations associated with making cavities within an electronic package. Subsequent FIGS. 5-16 provide more detailed illustrations associated with the various operations presented in FIG. 4.

Cavity formation process 100 generally includes a block 102 at which a particular configuration of one or more electronic components are provided. These electronic components may be, for example, suitably arranged on, and temporarily adhered to, a glass carrier or any other suitable structure. At a block 104, solder material is deposited on the terminals of the electronic components at which the desired cavities are to be formed. In alternative embodiments, the deposition of solder material at block 104 may be performed prior to the electronic components being arranged on the temporary carrier.

At a block 106, the electronic components and the solder material are encapsulated in an encapsulant, e.g., a mold compound. At a block 108, a top surface of the solder material is exposed from the encapsulant. For example, a grinding operation is performed to expose the top surface of the solder material. At a block 110, the solder material that was exposed at block 108 is removed by a hot air solder removal process. By way of example, flux may be applied to the exposed solder material, the solder material is locally heated using hot air in order to melt the solder material, and the melted solder material is removed by vacuum. In another example, the solder material may be removed by a solder wicking technique. After the melted solder material is removed, a cavity extending through the encapsulant remains at that location. Thereafter, cavity formation process 100 ends.

FIGS. 5-16 are described in connection with the fabrication of PoP device 60 (FIG. 3) in order to demonstrate the various operations of cavity formation process 100. Furthermore, the fabrication of a single PoP device 60 is illustrated and described in connection with FIGS. 5-16 for simplicity of illustration. Those skilled in the art will recognize that multiple PoP devices 60 may be fabricated concurrently in accordance with wafer level fabrication methodology. Moreover, such methodology is further suited for implementation in connection with a fan-out wafer level fabrication process in which the contact positions of the original semiconductor die are “fanned out” to a larger footprint.

Now referring to FIGS. 4 and 5, FIG. 5 shows a side sectional view of a structure at an initial stage 112 of processing in accordance with blocks 102 and 104 of cavity formation process 100. Accordingly, as shown, electronic components 62 and 64 are positioned on a carrier 114 utilizing, for example, a robotic component placement system, commonly referred to as a pick-and-place machine. Prior to or following placement of electronic component 62 onto glass carrier 114, solder material 116 is deposited on one or more terminals 68 of electronic component 62. In the illustrated embodiment, solder material 116 includes a plurality of solder balls 116, where one each of solder balls 116 is formed on one or more terminals 68.

Referring to FIGS. 4 and 6, FIG. 6 shows a side sectional view of the structure of FIG. 5 at a subsequent stage 118 of processing in accordance with block 106 of cavity formation process 100. At stage 118, electronic components 62, 64 and solder balls 116 are encapsulated in encapsulant 32. Note that solder balls 116 are fully embedded within encapsulant 32 at stage 118. Encapsulant 32 may be cured at an elevated temperature. Consequently, an appropriate solder material having a higher melting temperature than the temperature needed to cure encapsulant 32 is utilized to form solder balls 116.

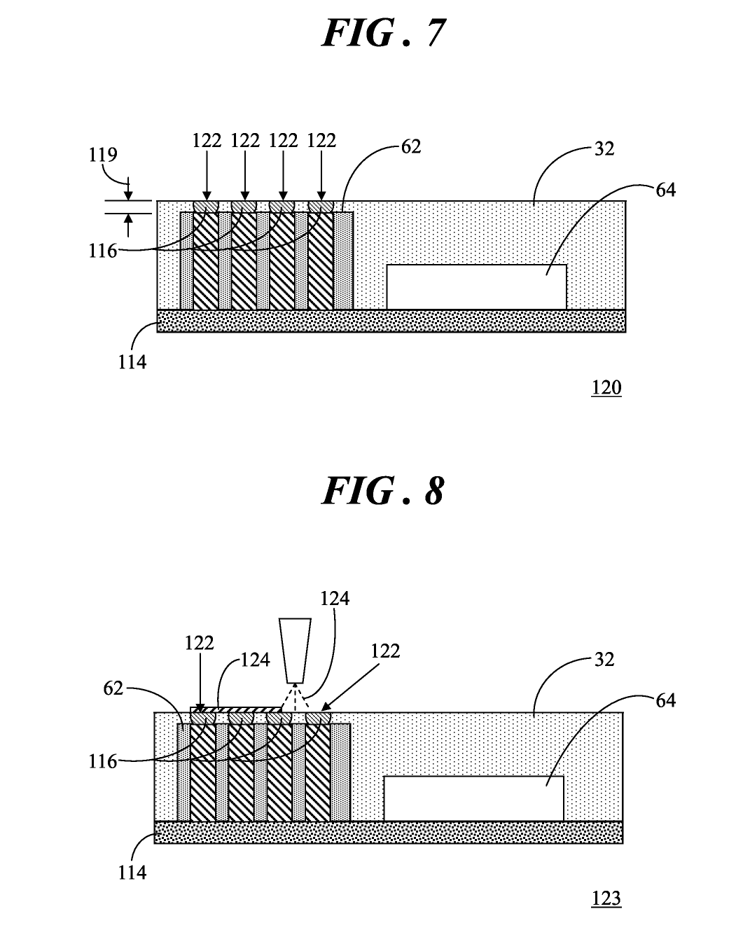

With reference to FIGS. 4 and 7, FIG. 7 shows a side sectional view of the structure of FIG. 6 at a subsequent stage 120 of processing in accordance with block 108 of cavity formation process 100. At stage 120, a top surface 122 of each solder ball 116 is exposed from encapsulant 32. By way of example, a grinding process may be performed to expose top surfaces 122 of solder balls 116 from encapsulant 32 while retaining encapsulant 32 between adjacent solder balls 116. In a preferred embodiment, grinding is performed to or lower than the largest diameter of solder balls 116 (FIG. 6) so that a height 119 of the portion of solder balls 116 still remaining after grinding yields a cavity of a size and shape sufficient to produce reliable final solder joint structures.

Now referring to FIGS. 4 and 8, FIG. 8 shows a side sectional view of the structure of FIG. 7 at a subsequent stage 123 of processing in accordance with block 110 of cavity formation process 100. At stage 123, a flux material 124 may be applied over the exposed top surfaces 122 of solder balls 116. Flux material 124 functions to remove metal oxides which might otherwise prevent the two metal surfaces (e.g., solder-to-copper, solder-to-solder, etch) from metallurgically bonding. Flux material 124 may also act as a flowing agent to facilitate soldering when interconnecting top electronic package 24 with bottom electronic package 66 (FIG. 2).

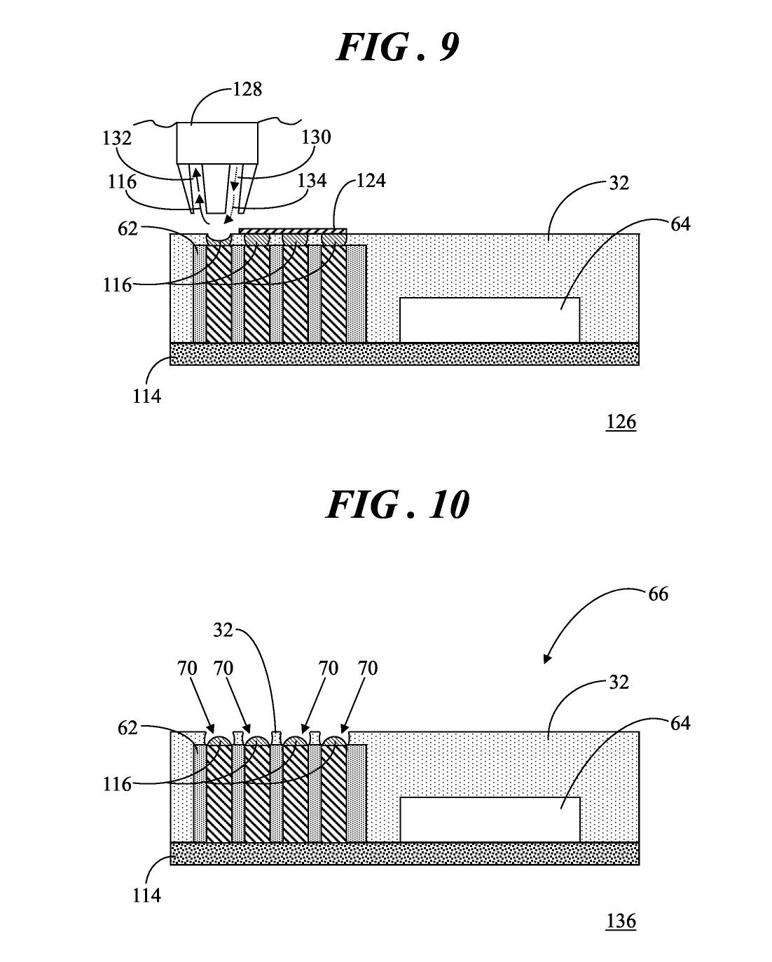

Referring to FIGS. 4 and 9, FIG. 9 shows a side sectional view of the structure of FIG. 8 at a subsequent stage 126 of processing in accordance with block 110 of cavity formation process 100. At stage 126, a hot air solder removal process is performed to remove solder balls 116. By way of example, a hot air solder removal tool 128 having a hot air delivery port 130 and a vacuum port 132 may be used. Hot air 134 (represented by dotted arrows) may be ejected from hot air delivery port 130 to locally heat and consequently melt solder balls 116. The melted solder material 116 as well as flux material 124 is then drawn into vacuum port 132 via suction action. The localized heating of solder balls 116 to a reflow temperature largely prevents the embedded electronic components 62, 64 from being exposed to excessive heat that might otherwise damage electronic components 62, 64.

Referring to FIG. 10, FIG. 10 shows a side sectional view of the structure of FIG. 9 at a subsequent stage 136 of processing. At stage 136 following the removal of solder material 116, individual cavities 70 remain at locations wherein solder material 116 was removed via the hot air solder removal process to yield bottom electronic package 66. These cavities 70 are separated and electrically isolated from the neighboring cavities 70 by the remaining encapsulant 32 located between them. As shown, some solder material 116 may remain in cavities 70 following solder removal. Some solder material 116 may remain due to the relatively high surface tension between solder material 116 and the underlying terminals 68 which prevents at least a small portion of solder material from being removed. In other embodiments, however, all of solder material 116 may be removed from cavities 70.

Now referring to FIGS. 4 and 11, FIG. 11 shows a side sectional view of a structure at an initial stage 138 of processing in accordance with another embodiment. As shown, electronic components 62 and 64 are positioned on carrier 114 in accordance with block 102. However, prior to or following placement of electronic component 62 onto glass carrier 114, solder material 140 is deposited on one or more terminals 68 of electronic component 62. In the illustrated embodiment, solder material 140 is a single sheet material, referred to herein as a solder preform 140. Solder preform 140 is positioned such that it spans across multiple terminals 68.

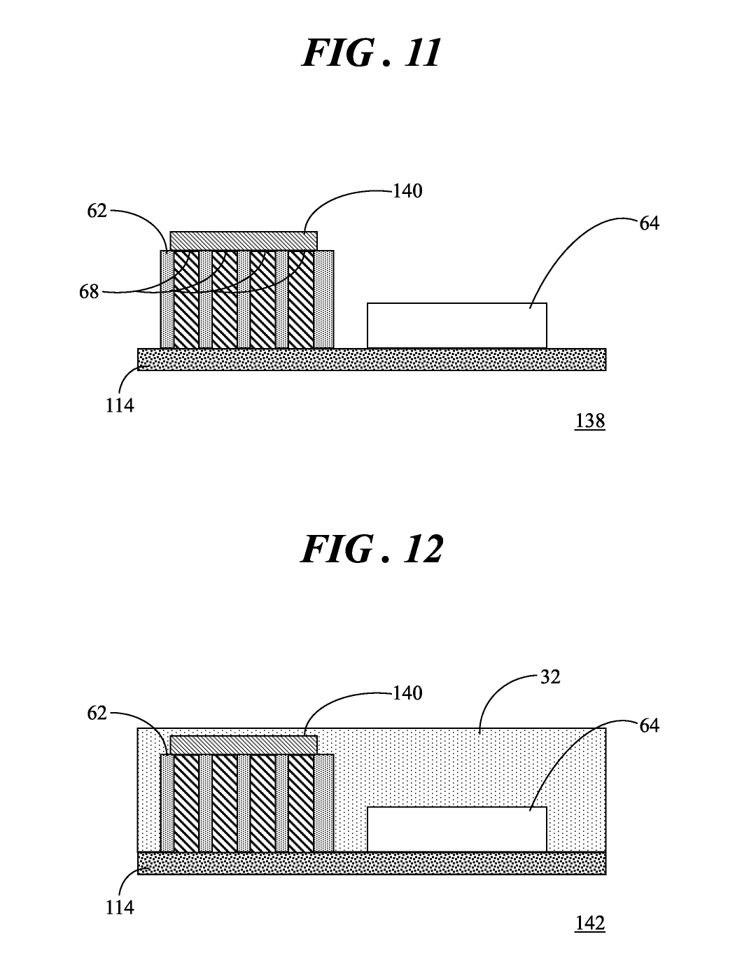

Referring to FIGS. 4 and 12, FIG. 12 shows a side sectional view of the structure of FIG. 11 at a subsequent stage 142 of processing in accordance with block 106 of cavity formation process 100. At stage 142, electronic components 62, 64 and solder preform 140 are encapsulated in encapsulant 32. Again note that solder preform 140 may be fully embedded within encapsulant 32 at stage 142. Encapsulant 32 may be cured at an elevated temperature. Consequently, an appropriate solder material having a higher melting temperature than the temperature needed to cure encapsulant 32 is utilized to form solder preform 140.

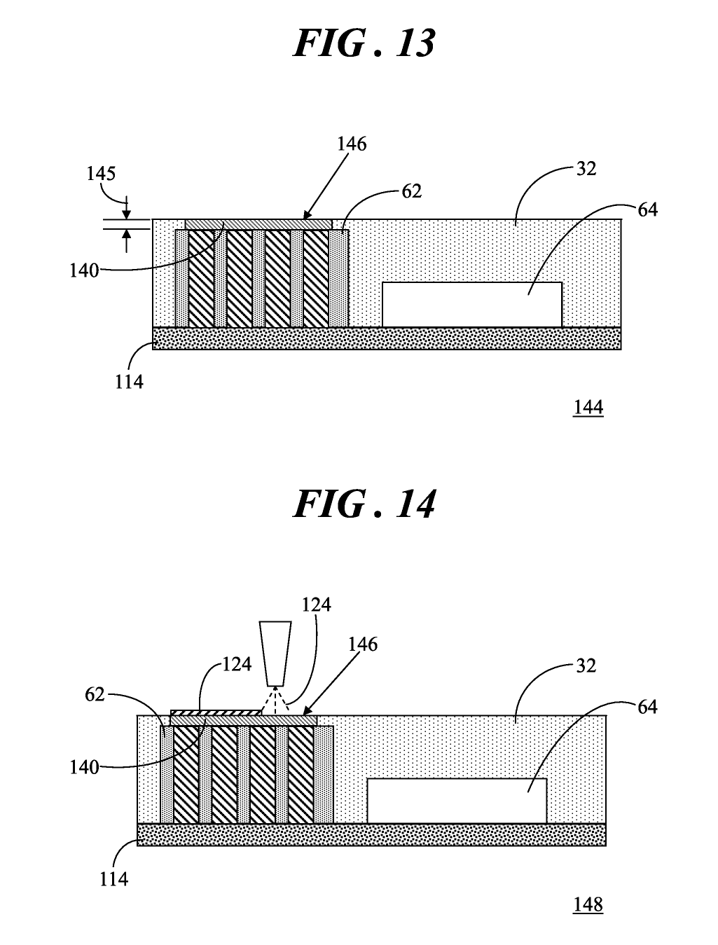

With reference to FIGS. 4 and 13, FIG. 13 shows a side sectional view of the structure of FIG. 12 at a subsequent stage 144 of processing in accordance with block 108 of cavity formation process 100. At stage 144, a top surface 146 of solder preform 140 is exposed from encapsulant 32 by implementing, for example, a grinding process. In an embodiment, a height 145 of the remaining solder preform 140 following grinding may be approximately one half of the stand-off of solder balls 52 (FIG. 1) of top electronic package 24 (FIG. 1). It should be readily observed that following the grinding process, at least some of solder preform 140 remains spanning between terminals 68, instead of the encapsulant 32 as shown in the illustrated embodiment of FIG. 10.

Now referring to FIGS. 4 and 14, FIG. 14 shows a side sectional view of the structure of FIG. 13 at a subsequent stage 148 of processing in accordance with block 110 of cavity formation process 100. At stage 148, flux material 124 may be applied over the exposed top surface 146 of solder preform 140.

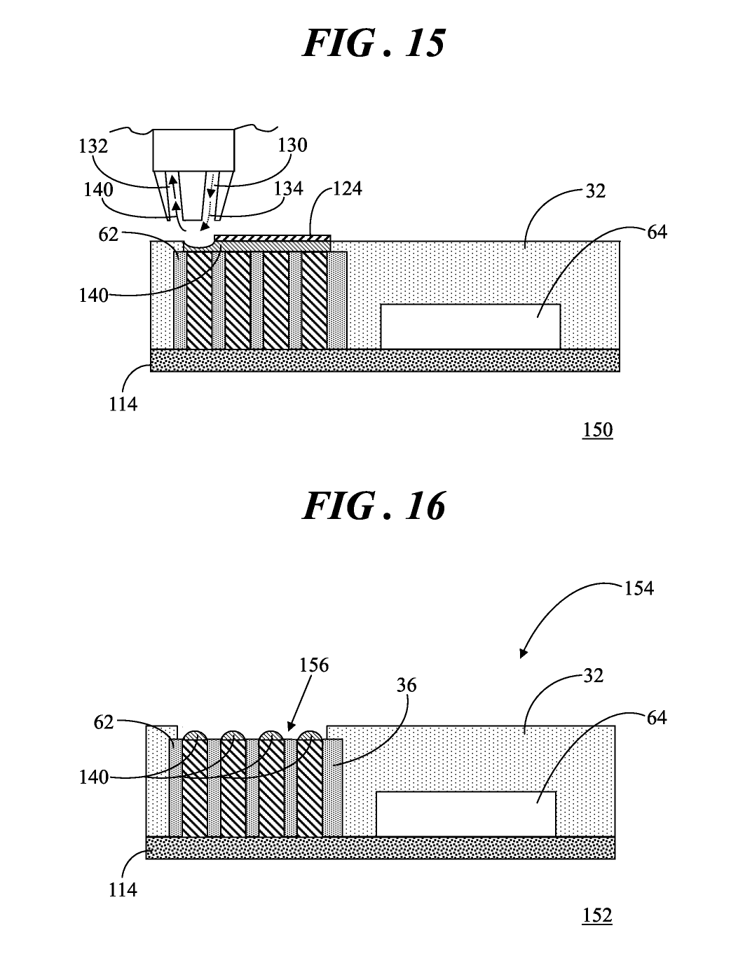

With reference to FIGS. 4 and 15, FIG. 15 shows a side sectional view of the structure of FIG. 14 at a subsequent stage 150 of processing in accordance with block 110 of cavity formation process 100. At stage 150, a hot air solder removal process is performed to remove solder preform 140. By way of example, hot air 134 may be ejected from hot air delivery port 130 of hot air solder removal tool 128. Hot air 134 locally heats and consequently melts a region of solder preform 140. The melted solder material 140 as well as flux material 124 is then drawn into vacuum port 132 via suction action. Again, the localized heating of solder preform 140 to a reflow temperature largely prevents the embedded electronic components 62, 64 from being exposed to excessive heat that might otherwise damage electronic components 62, 64.

FIG. 16 shows a side sectional view of the structure of FIG. 15 at a subsequent stage 152 of processing. At stage 152 following the removal of solder material 140, a bottom electronic package 154 is produced having a single cavity 156, i.e., an open mold, in which multiple terminals 68 are located. Due to the differing surface tensions of terminals 68 and the surrounding substrate material 36 of electronic component 62, some solder material 140 may remain on terminals 68. However, the hot air solder removal process removes all of solder material 140 that is in contact with substrate material 36 between adjacent terminals 68 so that adjacent terminals 68 will be electrically isolated from one another.

Regarding the two embodiments illustrated in FIGS. 10 and 16, FIG. 10 demonstrates an embodiment in which multiple cavities 70 are formed and FIG. 16 demonstrates an embodiment in which a single cavity 154 is formed. In the embodiment of FIG. 10, each of cavities 70 is suitably sized to act as an individual mold to accommodate a single solder ball 52 of top electronic package 24 and to shape the solder joint between the solder ball 52 and its associated terminal 68 (FIG. 2). Therefore, the individual molds may facilitate alignment and retention of the individual solder balls 52 with the underlying terminals 68. However, the shape of the individual molds may not be the same shape from top to bottom. For example, the individual molds may be narrower at the tops and bottoms, relative to a relatively wider the midsections of the individual molds. This inconsistent shape might potentially result in undesirably high stress concentrations in the solder joint. Conversely, in the embodiment of FIG. 16, the single cavity 154 (i.e., open mold) approach may enable the solder joints between solder balls 52 and terminals 68 to form uniformly thereby avoiding the undesirably high stress concentrations of the embodiment of FIG. 10. However, there may potentially be greater risk of shorting between the solder joints since there is no intervening encapsulant 32 between the neighboring terminals 68.

FIG. 17 shows a flowchart of a package-on-package (PoP) fabrication process 160 that incorporates cavity formation process 100 of FIG. 4. At a block 162 of PoP process 160, a first electronic package (e.g., bottom electronic package 66 of FIG. 10 or bottom electronic package 154 of FIG. 16) is produced, or manufactured, to include one or more cavities formed by solder removal in accordance with cavity formation process 100.

At a block 164, a second electronic package (e.g., top electronic package 24 of FIG. 1) is provided. The second electronic package may be fabricated at the same facility that is executing PoP fabrication process 160. Alternatively, the second electronic package may be provided by an external fabrication or distribution facility. At a block 166, the solder balls (e.g., solder balls 52) of the second electronic package (e.g., top electronic package 24) are positioned in the one or more cavities (e.g., cavities 34 of FIG. 10 or cavity 70 of FIG. 16) extending through the encapsulant (e.g., encapsulant 32) of the first electronic package (e.g., bottom electronic package 66 or bottom electronic package 154). In some embodiments, flux may be applied to the exposed terminals (e.g., terminals 28 or terminals 68) via a flux spray process, a flux paste print process, by a flux paste dip process, and so forth prior to positioning the solder balls of the second electronic package into the one or more cavities extending through the encapsulant of the first electronic package. Alternatively, the flux may be applied to the solder balls of the second electronic package.

At a block 168, the solder balls (e.g., solder balls 52) of the second electronic package (e.g., top electronic package 24) are attached to the terminals (e.g., terminals 28 of FIG. 1 or terminals 68 of FIG. 2) within the one or more cavities (e.g., cavities 34 or cavity 70). For example, a solder reflow process is performed in order to couple the top electronic package with the bottom electronic package. Following block 168, subsequent operations may entail the formation of redistribution layer 40 (FIG. 1), deposition of solder balls 48 (FIG. 1), testing, and so forth prior to the end of PoP fabrication process 160.

It is to be understood that certain ones of the process blocks depicted in FIGS. 4 and 17 may be performed in parallel with each other or with performing other processes. Furthermore, it is to be understood that the particular ordering of the process blocks depicted in FIGS. 4 and 17 may be modified, while achieving substantially the same result. Accordingly, such modifications are intended to be included within the scope of the inventive subject matter. In addition, although particular system configurations are described in conjunction with FIGS. 1-3, above, embodiments may be implemented in systems having other architectures, as well. These and other variations are intended to be included within the scope of the inventive subject matter.

Thus, various embodiments of a PoP device, a method of cavity formation by solder removal for package interconnections, a method for fabricating the PoP device that incorporates the cavity formation methodology, and a PoP device fabricated using the aforementioned methodology have been described. An embodiment of a method of forming a cavity in an electronic package, the electronic package including an electronic component, comprises depositing solder material on at least one terminal of the electronic component, encapsulating the electronic component and the solder material in an encapsulant, exposing a top surface of the solder material from the encapsulant, and removing the solder material such that the cavity remains at a location where the solder material was removed.

An embodiment of a method of fabricating a PoP device comprises forming a first electronic package, where the forming operation includes providing a first electronic component, the first electronic component having a plurality of terminals, depositing solder material on each of the terminals of the first electronic component, encapsulating the first electronic component and the solder material in an encapsulant, exposing a top surface of the solder material from the encapsulant, and removing the solder material such that at least one cavity remains at a location where the solder material was removed. The method further comprises providing a second electronic package, the second electronic package having a second electronic component and solder balls extending from an active surface of the second electronic component, positioning the solder balls of the second electronic package in the at least one cavity with one each of the solder balls in alignment with one each of the terminals, and attaching the solder balls to the terminals to couple the second electronic package with the first electronic package.

An embodiment of a PoP device comprises a first electronic package, the first electronic package including a first electronic component having a plurality of terminals, an encapsulant encapsulating the first electronic component and the plurality of terminals, and a single cavity at least temporarily extending through the encapsulant to expose the plurality of terminal located in the cavity. The PoP device further includes a second electronic package, the second electronic package having a second electronic component and solder balls extending from an active surface of the second electronic component, wherein the solder balls are positioned in the single cavity with one each of the solder balls in alignment with one each of the terminals and the solder balls are attached to the terminals to couple the second electronic package with the first electronic package.

The cavity formation methodology provides high throughput and damage free formation of mold cavities by the use of hot air/vacuum removal of solder material embedded in a mold compound. The hot air solder removal process yields mold cavities having consistent sizes and shapes, while limiting the potential for damage to the surrounding mold compound. Such consistency can facilitate the appropriate alignment of the solder balls of the top electronic package with the mold cavities, thereby enhancing solder joint reliability. Consequently, the mold cavities may be used for the purpose of package to package interconnection, such as in a PoP configuration. Additionally or alternatively, the cavity formation methodology may be used to form package interconnections on top of an electronic package for interconnection with other components such as surface mount devices. And still further, the cavity formation methodology may be used to form electrically conductive pads for probing the top side of an electronic package during testing of the package individually or after it has been assembled to a PCB.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A method of forming a cavity in an electronic package, said electronic package including an electronic component, and said method comprising:
depositing solder material on at least one terminal of said electronic component;
encapsulating said electronic component and said solder material in an encapsulant;
exposing a top surface of said solder material from said encapsulant; and
following said exposing operation, removing said solder material such that said cavity remains at a location where said solder material was removed, wherein said removing operation removes said top surface of said solder material and at least a portion of said solder material below said top surface to produce said cavity.

2. The method of claim 1 wherein said electronic component includes a plurality of terminals, said solder material comprises a plurality of solder balls, and said depositing comprises forming one each of said plurality of solder balls on one each of said plurality of terminals.

3. The method of claim 2 wherein:
said exposing comprises retaining said encapsulant between adjacent solder balls of said plurality of solder balls; and
said removing removes each of said plurality of solder balls of said plurality of solder balls to form a plurality of cavities, said cavity being one of said plurality of cavities.

4. The method of claim 1 wherein said electronic component includes a plurality of terminals, said solder material comprises a single sheet material, and said depositing comprises positioning said single sheet material such that said single sheet material spans across each of said plurality of terminals.

5. The method of claim 4 wherein:
said exposing comprises retaining said single sheet material spanning between adjacent terminals of said plurality of terminals; and
said removing removes said single sheet material such that said cavity is a single cavity in which said plurality of terminals are located and removes said single sheet material from between said adjacent terminals such that said adjacent terminals are electrically isolated from one another.

6. The method of claim 1 wherein said exposing comprises grinding said encapsulant to expose said top surface of said solder material.

7. The method of claim 1 wherein said removing comprises performing a hot air solder removal process to remove said solder material.

8. The method of claim 1 wherein said removing comprises:
locally heating said solder material to melt said solder material; and
removing said melted solder material by vacuum to produce said cavity.

9. The method of claim 8 further comprising applying flux to said solder material prior to said locally heating said solder material.

10. A method of fabricating a package-on-package device comprising:
forming a first electronic package, said forming said first electronic package including:
providing a first electronic component, said first electronic component having a plurality of terminals;
depositing solder material on each of said plurality of terminals of said first electronic component;
encapsulating said first electronic component and said solder material in an encapsulant;
exposing a top surface of said solder material from said encapsulant; and
following said exposing operation, removing said solder material such that at least one cavity remains at a location where said solder material was removed, wherein said removing operation removes said top surface of said solder material and at least a portion of said solder material below said top surface to produce said cavity;
providing a second electronic package, said second electronic package having a second electronic component and solder balls extending from an active surface of said second electronic component;
positioning said solder balls of said second electronic package in said at least one cavity with one each of said solder balls in alignment with one each of said plurality of terminals; and
attaching said solder balls to said plurality of terminals to couple said second electronic package with said first electronic package.

11. The method of claim 10 wherein said solder balls are first solder balls, said solder material comprises a plurality of second solder balls, and said depositing comprises forming one each of said plurality of second solder balls on one each of said plurality of terminals.

12. The method of claim 11 wherein:
said exposing comprises retaining said encapsulant between adjacent ones of said plurality of second solder balls;
said removing removes each of said plurality of second solder balls to form a plurality of cavities; and
said positioning positions said one each of said first solder balls in one each of said plurality of cavities.

13. The method of claim 12 wherein said exposing and said removing produces said plurality of cavities each of which is characterized by a cavity volume that is approximately equivalent to a material volume of each of said first solder balls extending from said active surface of said second electronic component.

14. The method of claim 10 wherein said solder material comprises a single sheet material, and said depositing comprises positioning said single sheet material such that said single sheet material spans across each of said plurality of terminals.

15. The method of claim 14 wherein:
said exposing comprises retaining said single sheet material spanning between adjacent terminals of said plurality of terminals;
said removing removes said single sheet material such that said cavity is a single cavity in which said plurality of terminals are located and removes said single sheet material from between said adjacent terminals such that said adjacent terminals are electrically isolated from one another; and
said positioning positions said solder balls in said single cavity in alignment with said plurality of terminals.

16. The method of claim 10 wherein said exposing comprises grinding said encapsulant to expose said top surface of said solder material.

17. The method of claim 10 wherein said removing comprises:
locally heating said solder material to melt said solder material; and
removing said melted solder material by vacuum to produce said cavity.

18-20. (canceled)
